(19) United States
(12) Patent Application Publication
(10) Pub. No.: US 2026/0218411 A1
(43) Pub. Date: Jul. 30, 2026

(54) PLATE AND ABSORPTIVE MASS ARRANGEMENTS FOR LOCALIZED THERMAL ADJUSTABILITY, AND RELATED METHODS AND PROCESSING CHAMBERS

(71) Applicant: Applied Materials, Inc., Santa Clara, CA (US)

(72) Inventors: Zhepeng CONG, San Jose, CA (US); Saurabh CHOPRA, Santa Clara, CA (US); Abhishek DUBE, Fremont, CA (US)

(21) Appl. No.: 19/039,671

(22) Filed: Jan. 28, 2025

(51) Int. Cl. C30B 25/14; C30B 25/10

(52) U.S. Cl. CPC C30B 25/14; C30B 25/10

(57) ABSTRACT

The present disclosure relates to plate and absorptive mass arrangements for localized thermal adjustability, and related methods and processing chambers. In one or more embodiments, a processing chamber includes a chamber body at least partially defining an internal volume, a substrate support disposed in the internal volume, a plate apparatus disposed in the internal volume and at least partially defining a processing volume between the plate apparatus and the substrate support. The plate apparatus includes one or more flow openings formed in one or more plate walls. The processing chamber includes one or more absorptive masses disposed in the one or more flow openings.

### BACKGROUND

### Field

The present disclosure relates to plate and absorptive mass arrangements for localized thermal adjustability, and related methods and processing chambers.

### Description of the Related Art

Semiconductor substrates are processed for a wide variety of applications, including the fabrication of integrated devices and micro-devices. One method of processing substrates includes depositing a material, such as a dielectric material or a semiconductive material, on an upper surface of the substrate. The material may be deposited in a lateral flow chamber by flowing a process gas parallel to the surface of a substrate positioned on a support, and thermally decomposing the process gas to deposit a material from the gas onto the substrate surface.

However processing can be limited with respect to uniformity, such as film thickness deposition uniformity and/or dopant uniformity. For example, non-uniformities can occur on localized areas of processed substrates, which can hinder device performance.

Therefore, a need exists for improved process chambers and methods.

### SUMMARY

The present disclosure relates to plate and absorptive mass arrangements for localized thermal adjustability, and related methods and processing chambers.

In one or more embodiments, a processing chamber includes a chamber body at least partially defining an internal volume, a substrate support disposed in the internal volume, a plate apparatus disposed in the internal volume and at least partially defining a processing volume between the plate apparatus and the substrate support. The plate apparatus includes one or more flow openings formed in one or more plate walls. The processing chamber includes one or more absorptive masses disposed in the one or more flow openings.

In one or more embodiments, a chamber kit includes a plate apparatus that includes one or more flow openings formed in one or more plate walls, and one or more absorptive masses sized and shaped for disposition in the one or more flow openings. The one or more absorptive masses have a higher absorptivity than the plate apparatus.

In one or more embodiments, a method of substrate processing includes heating a substrate support in a processing volume of a processing chamber, and flowing one or more process gases between the substrate support and a plate apparatus spaced from the substrate support. The method includes flowing a gas into one or more flow openings of the plate apparatus and past one or more absorptive masses disposed in the one or more flow openings.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is a partial schematic side cross-sectional view of a processing chamber, according to one or more embodiments.

FIG. 2 is a schematic partial perspective view of the chamber kit shown in FIG. 1, according to one or more embodiments.

FIG. 3 is a schematic partial top view of the chamber kit, according to one or more embodiments.

FIG. 4 is a side cross-sectional view, along Section 4-4, of the chamber kit shown in FIG. 3, according to one or more embodiments.

FIGS. 5 and 6 are a side cross-sectional views, along Section 5-5, of the absorptive mass shown in FIG. 3, according to one or more embodiments.

FIG. 7 is a schematic partial top view of the process chamber, according to one or more embodiments.

FIG. 8 is a schematic block diagram view of a method of substrate processing for semiconductor manufacturing, according to one or more embodiments.

FIG. 9 is a side cross-sectional view, along Section 4-4, of the chamber kit shown in FIG. 3, according to one or more embodiments.

FIG. 10 is a schematic partial top view of the chamber kit in fluid communication with an injector, according to one or more embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The present disclosure relates to plate and absorptive mass arrangements for localized thermal adjustability, and related methods and processing chambers.

The disclosure contemplates that terms such as “couples,” “coupling,” “couple,” and “coupled” may include but are not limited to embedding, bonding, welding, fusing, melting together, interference fitting, and/or fastening such as by using bolts, threaded connections, pins, and/or screws. The disclosure contemplates that terms such as “couples,” “coupling,” “couple,” and “coupled” may include but are not limited to integrally forming. The disclosure contemplates that terms such as “couples,” “coupling,” “couple,” and “coupled” may include but are not limited to direct coupling and/or indirect coupling, such as indirect coupling through components such as links, blocks, and/or frames.

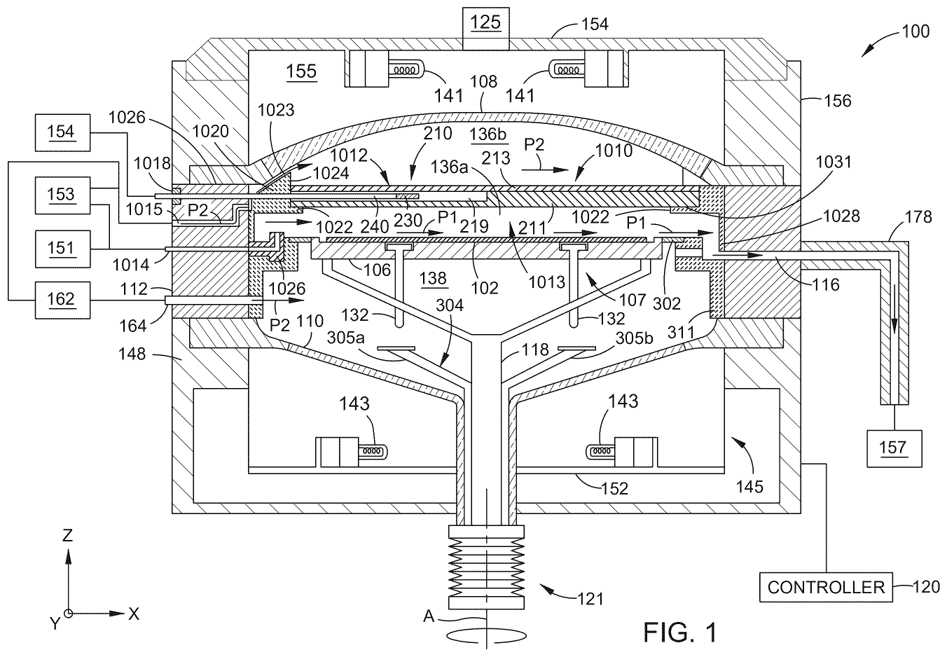

FIG. 1 is a partial schematic side cross-sectional view of a processing chamber 1000, according to one or more embodiments. The processing chamber 1000 is a deposition chamber. In one or more embodiments, the processing chamber 1000 is an epitaxial deposition chamber. In one or more embodiments, the processing chamber 1000 is utilized to grow an epitaxial film on a substrate 102. The processing chamber 1000 creates a cross-flow of precursors across a top surface of the substrate 102. The processing chamber 1000 is shown in a processing condition in FIG. 1.

The processing chamber 1000 includes an upper body 156, a lower body 148 disposed below the upper body 156, a flow module 112 disposed between the upper body 156 and the lower body 148. The upper body 156, the flow module 112, and the lower body 148 form a chamber body. Disposed within the chamber body is a substrate support 106, an upper plate 108 (such as an upper window and/or an upper dome), a lower plate 110 (such as a lower window and/or a lower dome), a plurality of upper heat sources 141, and a plurality of lower heat sources 143. As shown, a controller 120 is in communication with the processing chamber 100 and is used to control processes and methods, such as the operations of the methods described herein. The present disclosure contemplates that each of the heat sources described herein can include one or more of: lamp(s), resistive heater(s), light emitting diode(s) (LEDs), and/or laser(s). The present disclosure contemplates that other heat sources can be used.

The substrate support 106 is disposed between the upper plate 108 and the lower plate 110. The substrate support 106 includes a support face that supports the substrate 102. The plurality of upper heat sources 141 are disposed between the upper window and a lid 154. The plurality of upper heat sources 141 form a portion of the upper heat source module 155. The lid 154 may include a plurality of sensors disposed therein or thereon for measuring the temperature within the processing chamber 100. The plurality of lower heat sources 143 are disposed between the lower plate 110 and a floor 152. The plurality of lower heat sources 143 form a portion of a lower heat source module 145. In one or more embodiments, the upper plate 108 is an upper dome and is formed of an energy transmissive material, such as quartz. In one or more embodiments, the lower plate 110 is a lower dome and is formed of an energy transmissive material, such as quartz. A pre-heat ring 302 is disposed outwardly of the substrate support 106. A stop 304 includes a plurality of arms 305a, 305b that each include a lift pin stop on which at least one of the lift pins 132 can rest when the substrate support 106 is lowered (e.g., lowered from a process position to a transfer position).

The internal volume has the substrate support 106 disposed therein. The substrate support 106 includes a top surface on which the substrate 102 is disposed. The substrate support 106 is attached to a shaft 118. The shaft 118 is connected to a motion assembly 121. The motion assembly 121 includes one or more actuators and/or adjustment devices that provide movement and/or adjustment for the shaft 118 and/or the substrate support 106.

The substrate support 106 may include lift pin perforations 107 disposed therein. The lift pin perforations 107 are sized to accommodate a lift pin 132 for lifting of the substrate 102 from the substrate support 106 either before or after a deposition process is performed.

A chamber kit 1010 includes a plate apparatus 210 disposed in the internal volume and at least partially defining a processing volume 136a between the plate apparatus 210 and the substrate support 106. The plate apparatus 210 has a first outer face 1012 and a second outer face 1013 opposing the first outer face 1012. The plate apparatus 210 includes one or more plates 211, 213 (two are shown in FIG. 1). The second outer face 1013 faces the substrate support 106. The plate apparatus 210 includes one or more flow openings 219 formed in one or more plate walls of the one or more plates 211, 213. The chamber kit 1010 includes one or more absorptive masses 230 disposed in the one or more flow openings 219. The one or more absorptive masses 230 having a higher absorptivity and/or a higher emissivity than the one or more plates 211, 213 of the plate apparatus 210. The one or more absorptive masses 230 are respectively coupled to one or more conduits 240 disposed in the one or more flow openings 219. The one or more conduits 240 are in fluid communication with one or more heat transfer sources 154 that supply one or more heat transfer fluids F1 to the one or more flow openings 219 through the one or more conduits 240. At least part of the plate apparatus 210 includes a transparent material (such as transparent quartz), an opaque material (such as opaque quartz (e.g. white quartz, or grey quartz; and/or black quartz), silicon carbide (SiC), and/or graphite coated with SiC), and/or one or more ceramics (such as alumina (aluminum oxide (Al₂O₃)), aluminum nitride (AlN), silicon nitride (Si₃N₄), Boron Nitride (BN), and/or Boron Carbide (B₄C))). In one or more embodiments, the plate apparatus 210 includes a transparent material (such as quartz) and opaque particles (such as SiC particles and/or Si particles) suspended in the transparent material. For example, the one or more plates 211, 213 can be formed of the transparent material and opaque particles suspended in the transparent material.

In one or more embodiments, the plate apparatus 210 includes a first plate 211 and a second plate 213 sized and shaped for disposition on the first plate 211 to define the one or more flow openings 219 between the first plate 211 and the second plate 213. For example, the one or more flow openings 219 can be one or more recesses formed in the first plate 211, and the second plate 213 can be a cover plate that covers the one or more recesses to form the one or more flow openings 219. The second plate 213 can rest on the first plate 211. The second plate 213 can be bonded (such as diffusion bonded), fused, and/or welded to the first plate 211. The first plate 211 and the second plate 213 can be integrally formed. For example, the plate apparatus 210 can be machined from a single plate.

The various openings (e.g., inlet openings, flow openings, and outlet openings) described herein are shown as holes and recesses. Other opening structures and shapes are contemplated. For example, the flow openings 219 can be part of tubes that are coupled (e.g., welded) to the first plate 211 and/or the second plate 213. As another example, the flow openings 219 can be holes machined into a plate.

In addition to or in place of the upper heat sources 141 and/or lower heat sources 143, one more targeted heat sources 125 are oriented toward the one or more absorptive masses 230 to heat the one or more absorptive masses 230. In one or more embodiments, the one or more targeted heat sources 125 are laser sources that emit laser beams toward the one or more absorptive masses 230. The one or more targeted heat sources 125 can heat the one or more absorptive masses 230 in addition to or in place of the upper heat sources 141 and/or the lower heat sources 143. The one or more targeted heat sources 125 can emit energy at a wavelength range that is different (such as broader) than a wavelength of energy emitted by the heat sources 141, 143. The one or more targeted heat sources 125 can be used to heat the one or more process gases P1 for gas activation.

The chamber body includes a first liner 1020 and a second liner 311. The second liner 311 is disposed below the first liner 1020. The pre-heat ring 302 is supported on a ledge of the second liner 311. At least part of the first liner 1020 is curved (e.g., annular). One or more inlet openings 1023 extending to an inner surface 1024 of the first liner 1020 are on a first side of the first liner 1020, and one or more second outlet openings 1025 are on a second side of the first liner 1020. The one or more inlet openings 1023 can be between the first liner 1020 and the upper plate 108. The first liner 1020 includes one or more ledges 1022 sized and shaped to support an outer region of the plate apparatus 210.

In the embodiment shown in FIG. 1, a lowermost end of the plate apparatus 210 is aligned above a lowermost end of the first liner 1020. In one or more embodiments, as shown in FIG. 1, the lowermost end of the plate apparatus 210 is part of the second outer face 1013, and the lowermost end of the first liner 1020 is part of an extension.

At least part of the plate apparatus 210 is in the shape of a disc, and at least part of the first liner 1020 is in the shape of a ring. It is contemplated, however, that the plate apparatus 210 and/or the first liner 1020 can be in the shape of a rectangle, or other geometric shapes. The plate apparatus 210 at least partially fluidly isolates an upper portion 136b of the internal volume from the processing volume 136a. The plate apparatus 210 at least partially defines the processing volume between the plate apparatus 210 and the substrate support 106.

The flow module 112 (which can define at least part of one or more sidewalls of the processing chamber 1000) includes one or more first gas inlets 1014 in fluid communication with the processing volume 136a of the internal volume. The flow module 112 includes one or more second inlet openings 1015 in fluid communication with the upper portion 136b of the internal volume. The one or more first gas inlets 1014 are in fluid communication with one or more flow gaps between the first liner 1020 and the second liner 311. One or more inject blocks 1026 having one or more flow openings formed therein can be disposed in one or more flow gaps between the first liner 1020 and the second liner 311. The one or more second inlet openings 1015 are in fluid communication with the one or more inlet openings 1023 above the first liner 1020. The first gas inlets 1014 are fluidly connected to one or more process gas sources 151 and one or more cleaning gas sources 153. The purge gas inlet(s) 164 are fluidly connected to one or more purge gas sources 162. The one or more gas exhaust outlets 116 are fluidly connected to an exhaust pump 157. One or more process gases supplied using the one or more process gas sources 151 can include one or more reactive gases (such as one or more of silicon-containing, phosphorus-containing, and/or germanium-containing gases, and/or one or more carrier gases (such as one or more of nitrogen (N₂) and/or hydrogen (H₂)). One or more purge gases supplied using the one or more purge gas sources 162 can include one or more inert gases (such as one or more of argon (Ar), helium (He), and/or nitrogen (N₂)). One or more cleaning gases and/or etching gases supplied using the one or more cleaning gas sources 153 can include one or more of hydrogen and/or chlorine (such as hydrochloric acid (HCl)). In one or more embodiments, the one or more process gases include silicon hydrides (such as one or more silanes and/or one or more chlorinated silanes), germanium (such as germane (GeH₄)), boron (such as diborane (B₂H₆)), and/or phospine (PH₃).

The one or more gas exhaust outlets 116 are further connected to or include an exhaust system 178. The exhaust system 178 fluidly connects the one or more gas exhaust outlets 116 and the exhaust pump 157. The exhaust system 178 can assist in the controlled deposition of a layer on the substrate 102. The exhaust system 178 is disposed on an opposite side of the processing chamber 100 relative to the flow module 112.

During a deposition operation (e.g., an epitaxial growth operation), the one or more process gases P1 flow through the one or more first gas inlets 1014, through the one or more gaps, and into the processing volume 136a to flow horizontally over the substrate support 106 and the substrate 102 and to the one or more gas exhaust outlets 116. During the deposition operation, one or more purge gases P2 flow through the one or more second inlet openings 1015, through the one or more inlet openings 1023 of the first liner 1020, and into the upper portion 136b. The one or more purge gases P2 flow simultaneously with the flowing of the one or more process gases P1. The flowing of the one or more purge gases P2 through the upper portion 136b facilitates reducing or preventing flow of the one or more process gases P1 into the upper portion 136b that would contaminate the upper portion 136b. The one or more process gases P1 are exhausted through exhaust gaps between the first liner 1020 and the second liner 311, and through the one or more gas exhaust outlets 116. The one or more purge gases P2 are exhausted through the one or more second outlet openings 1025, through the same exhaust gaps between the first liner 1020 and the second liner 311, and through the same one or more gas exhaust outlets 116 as the one or more process gases P1. The present disclosure contemplates that that one or more purge gases P2 can be separately exhausted through one or more second gas exhaust outlets that are separate from the one or more gas exhaust outlets 116.

The present disclosure also contemplates that one or more purge gases can be supplied to the purge volume 138 (through the plurality of purge gas inlets 164) during the deposition operation, and exhausted from the purge volume 138.

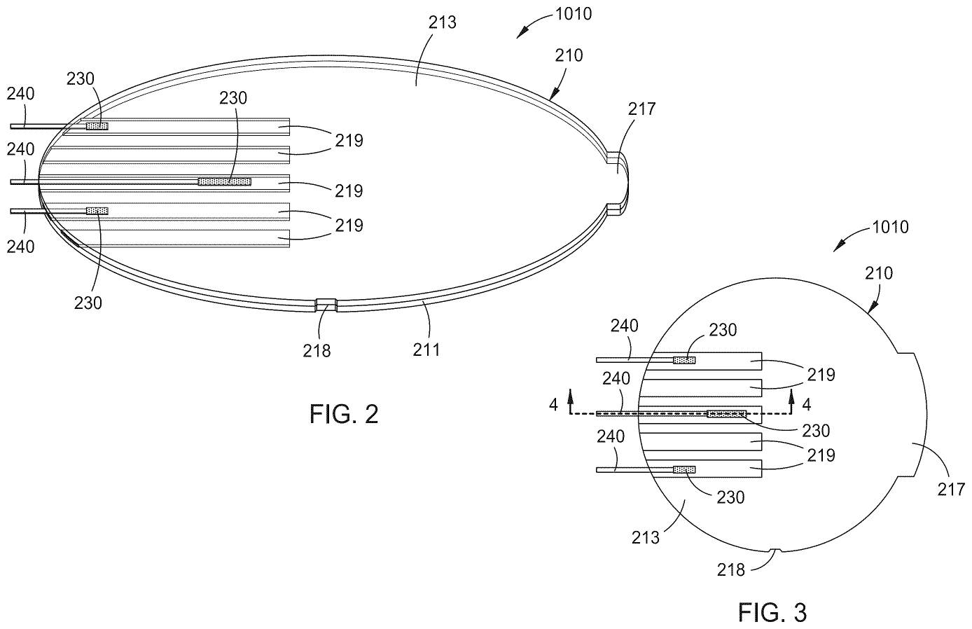

FIG. 2 is a schematic partial perspective view of the chamber kit 1010 shown in FIG. 1, according to one or more embodiments.

The plate apparatus 210 can include a flange section 217 that is sized and shaped to extend over a recessed portion 1031 (FIG. 1) of the first liner 1020. The plate apparatus 210 includes an opening 218 in an outer edge of the plate apparatus 210. Transfer equipment (such as heads of lift pins) can extend through the opening 218 the plate apparatus 210 is lowered onto the upper liner 1020. The flange section 217 can be used for location and/or retention of the plate apparatus 1010.

The one or more conduits 240 are adjustably disposed in the one or more flow openings 219 to adjust a position of the one or more absorptive masses 230. The absorptive masses 230 and the conduits 240 coupled thereto are independently adjustable across a variety of positions, such as by moving the respective conduit 240 in and out of the plate apparatus 210. For example, the respective conduits 240 can slide (inwardly and outwardly) within the respective flow openings 219. The absorptive masses 230 and the conduits 240 coupled thereto can be removed from the respective flow openings 219 (for omitted shadowing effect and omitted localized heating effect) and inserted into other flow openings 219. The one or more conduits 240 respectively are disposed in a seal 118 (such as a vacuum seal) and are movable in and out of the seal 118. The seal 118 is shown in FIG. 1, and can be disposed in the chamber body (such as in the flow module 112). The one or more conduits 240 can be moved manually, or can be moved using a mechanical system (such as a system including a motorized drive, bellows, and feedthroughs for the conduits 240).

FIG. 3 is a schematic partial top view of the chamber kit 1010, according to one or more embodiments.

As shown in FIG. 3, the absorptive masses 230 are disposed at different positions relative to a center of the plate apparatus 210.

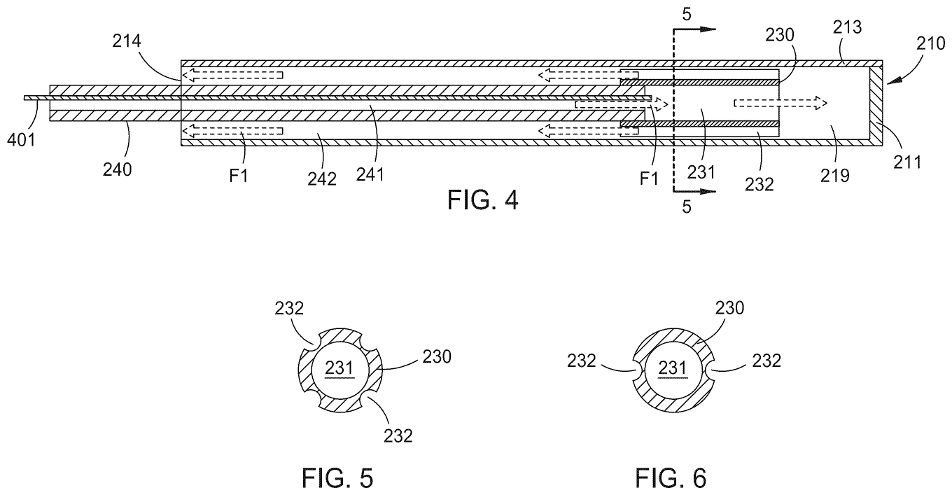

FIG. 4 is a side cross-sectional view, along Section 4-4, of the chamber kit 1010 shown in FIG. 3, according to one or more embodiments.

The one or more absorptive masses 230 include silicon carbide (SiC). In one or more embodiments, the one or more absorptive masses 230 are formed of SiC. In one or more embodiments, the one or more absorptive masses 230 are formed of graphite coated with SiC. In one or more embodiments, the one or more absorptive masses 230 are black bodies. In one or more embodiments, the one or more plate walls of the one or more plates 211, 213 and the one or more conduits 240 respectively include quartz (such as transparent quartz). In one or more embodiments, the one or more absorptive masses 230 are tips coupled to respective ends of the one or more conduits 240. In one or more embodiments, the conduit 240 is sized to extend into central opening 231 and the absorptive mass 230 is coupled to the conduit 240 using an interference fit. As discussed, the conduit 240 can be mechanically coupled to the absorptive mass 230 using an interference fit (such as an interference sleeve fit) and/or one or more pin inserts extending through the absorptive mass 230 and the conduit 240. Other coupling techniques are also contemplated.

The one or more conduits 240 respectively includes a first opening 241 formed therein, and the one or more conduits 240 are respectively positioned to form a second opening 242 (such as an annular opening) between the respective conduit 240 and at least one of the one or more plate walls of the one or more plates 211, 213. The one or more absorptive masses 230 respectively include a central opening 231 and one or more outer openings 232. The central opening 231 extends longitudinally along the respective absorptive mass 230. The first opening 241 of the conduit 240 aligned with the central opening 231 of at least one of the one or more absorptive masses 230. The one or more flow openings 219 extend into an edge surface 214 of the plate apparatus 210 and inward toward a center of the plate apparatus 210.

The heat transfer fluid F1 flows in the respective conduit 240 through the first opening 241 and into the central opening 231 of the respective absorptive mass 230. The heat transfer fluid F1 flows out of the central opening 231 and into the flow opening 219, and outwardly of the absorptive mass 230 through the one or more outer openings 232. The heat transfer fluid F1 flows into the second opening 242 and out of the flow opening 219 outwardly of the conduit 240. In one or more embodiments, the heat transfer fluid F1 is a cooling fluid at a lower temperature than the substrate 102 and the absorptive mass 230. In such an embodiment, the heat transfer fluid F1 cools the one or more absorptive masses 230 such that the one or more absorptive masses 230 block energy from the heat sources 141 for a shadowing effect on one or more areas of the substrate 102. In one or more embodiments, the heat transfer fluid F1 is a heating fluid at a higher temperature than the substrate 102 and the absorptive mass 230. In such an embodiment, the heat transfer fluid F1 heats the one or more absorptive masses 230 such that the one or more absorptive masses 230 emit energy toward the substrate 102 for a localized heating effect (such as a biased heating effect) on one or more areas of the substrate 102. The heating of the absorptive masses 230 can also be used to heat the one or more process gases P1 for gas activation.

The present disclosure contemplates that the heat transfer fluid F1 can be cooled and can flow to provide the shadow effect and then the flow of the heat transfer fluid F1 can be turned off, and the one or more targeted heat sources 125 can be turned on to heat the one or more absorptive masses 230 and provide the localized heating effect. The heating of the one or more targeted heat sources 125 can be used in place of or in addition to a heated heat transfer fluid F1.

A sensor 401 is disposed in one or more of the flow openings 219. In one or more embodiments, the sensor 401 is a thermocouple embedded in the conduit 240. Other sensors, such as pyrometer(s) and/or spectrometer(s), may be used for the sensor 401. The sensor 401 monitors temperatures of the absorptive mass 230, the heat transfer fluid F1, and/or the conduit 240.

FIGS. 5 and 6 are a side cross-sectional views, along Section 5-5, of the absorptive mass 230 shown in FIG. 3, according to one or more embodiments.

In FIG. 5 the absorptive mass 230 includes four outer openings 232, and in FIG. 6 the absorptive mass 230 includes two outer openings 232. The present disclosure contemplates that a different number of outer openings 232 may be used. In one or more embodiments, the one or more absorptive masses 230 respectively include a sleeve. The one or more outer openings 232 are azimuthally spaced from each other. In one or more embodiments, the one or more outer openings 232 are azimuthally spaced from each other equidistantly.

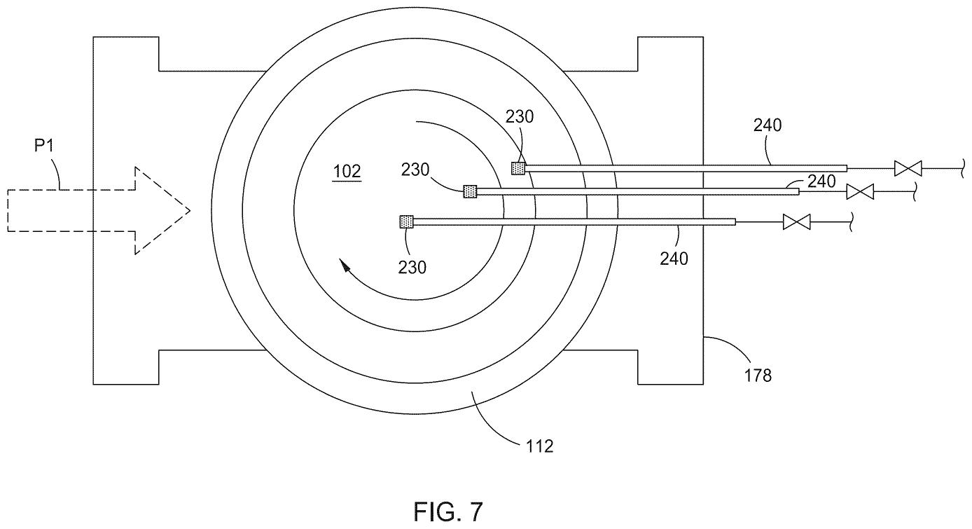

FIG. 7 is a schematic partial top view of the process chamber 1000, according to one or more embodiments.

One or more valves 701-703 are operable to flow the heat transfer fluid F1 respectively to the one or more conduits 240. In one or more embodiments, the heat transfer fluid F1 supplied to the respective conduits 240 differs with respect to one or more of composition, temperature, pressure, and/or flow rate (such as mass flow rate). The present disclosure contemplates that the one or more conduits 240 can extend through a sidewall of the chamber body on an exhaust side of the chamber body (as shown in FIG. 7), an inject side of the chamber body (as shown in FIG. 1), or any other azimuthal position along the chamber body.

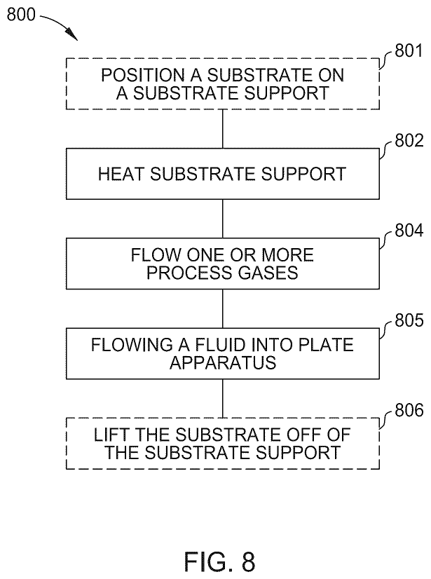

FIG. 8 is a schematic block diagram view of a method 800 of substrate processing for semiconductor manufacturing, according to one or more embodiments.

Optional operation 801 includes positioning a substrate on a substrate support in a processing volume of a processing chamber. In one or more embodiments, the positioning includes moving a substrate support and/or a plurality of lift pins relative to each other to land the substrate on the substrate support.

Operation 802 of the method 800 includes heating the substrate support and/or the substrate in the processing volume to a target temperature.

Operation 804 includes flowing one or more process gases between the substrate support and a plate apparatus (such as the plate apparatus 210) spaced from the substrate support. The one or more process gases flow over the substrate to form one or more layers on the substrate.

Operation 805 includes flowing a fluid (such as the heat transfer fluid F1) into one or more flow openings of the plate apparatus and past one or more absorptive masses disposed in the one or more flow openings. The fluid heats or cools the one or more absorptive masses. The fluid flows into the one or more flow openings through an inner flow path of the one or more absorptive masses, and the gas flows out of the plate apparatus through an outer flow path between the one or more absorptive masses and one or more plate walls of the plate apparatus. In one or more embodiments, the gas flow changes direction after flowing out inner flow path and before flowing into the outer flow path.

Optional operation 806 includes lifting the substrate off of the substrate support. In one or more embodiments, the lifting includes moving a substrate support and/or a plurality of lift pins relative to each other to engage the substrate with the lift pins and lift the substrate.

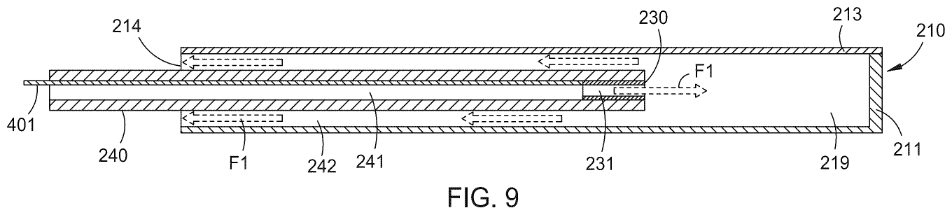

FIG. 9 is a side cross-sectional view, along Section 4-4, of the chamber kit 1010 shown in FIG. 3, according to one or more embodiments.

In the implementation shown in FIG. 9, at least part of the absorptive mass 230 is inserted into the first opening 241 of the respective conduit 240, such as by using an interference fit. In one or more embodiments, the one or more second openings 232 are omitted from the implementation shown in FIG. 9.

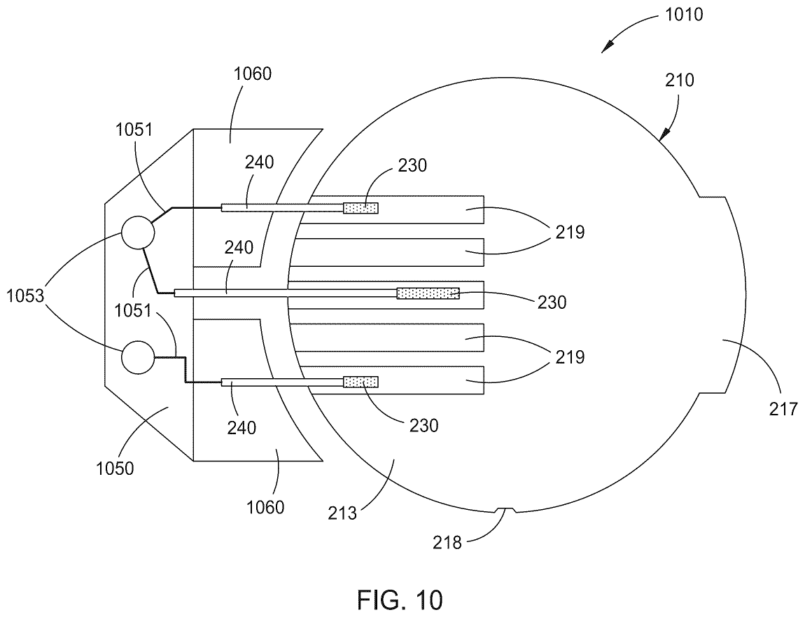

FIG. 10 is a schematic partial top view of the chamber kit 1010 in fluid communication with an injector 1050, according to one or more embodiments.

A plurality of gas lines 1051 are fluidly connected between the injector 1050 and the respective conduits 240. The injector 1050 includes one or more upper openings 1053 that supply the one or more heat transfer fluids F1 to the respective conduits 240 through the gas lines 1051. After flowing through the conduits 240, the one or more heat transfer fluids F1 can flow out of the one or more flow openings 219 and can flow to the purge volume 138, the processing volume 136a, the upper portion 136b, and/or the exhaust system 178. As an example, the one or more heat transfer fluids F1 can flow out of the one or more flow openings 219 and can flow to the exhaust system 178 through the flow module 112 and/or through gas lines outside of the flow module 112. One or more side openings of the injector 1050 can flow the one or more process gases P1 to the processing volume 136a through one or more gas boxes 1060.

The present disclosure contemplates that the injector 1050 can be part of the flow module 112 and/or can be used in addition to the flow module 112. The present disclosure contemplates that the gas lines 1051 can be fluidly connected to the flow openings 219 such that the one or more heat transfer fluids F1 can flow into the flow openings 219 and flow out through the respective conduits 240 and to the purge volume 138, the processing volume 136a, the upper portion 136b, and/or the exhaust system 178.

Benefits of the present disclosure include temperature adjustability and/or processing (e.g., deposition) adjustability without increasing chamber sizes and footprints; localized adjustment of increased thickness or reduced thickness; localized heating profiles; and localized shadowing profiles. Benefits also include adjustability of element (e.g., dopant) concentrations; adjustability of heat transfer; reduced diversive flow of process gases; enhanced deposition thicknesses; enhanced profiles of processing (e.g., deposition) uniformity; enhanced thermal uniformities; enhanced gas flow rate uniformities; enhanced selectivity adjustability; and increased throughput and efficiency; and reduced chamber downtime.

It is contemplated that one or more aspects disclosed herein may be combined. As an example, one or more aspects, features, components, operations and/or properties of the processing chamber 1000, the plate apparatus 210, the chamber kit 1010, the first liner 1020, the second liner 311, and/or the method 800 may be combined. Moreover, it is contemplated that one or more aspects disclosed herein may include some or all of the aforementioned benefits.

While the foregoing is directed to embodiments of the present disclosure, other and further embodiments of the disclosure may be devised without departing from the basic scope thereof, and the scope thereof is determined by the claims that follow.

1. A processing chamber, comprising:
a chamber body at least partially defining an internal volume;
a substrate support disposed in the internal volume;
a plate apparatus disposed in the internal volume and at least partially defining a processing volume between the plate apparatus and the substrate support, the plate apparatus comprising:
one or more flow openings formed in one or more plate walls; and
one or more absorptive masses disposed in the one or more flow openings.

2. The processing chamber of claim 1, wherein the one or more absorptive masses comprise silicon carbide (SiC).

3. The processing chamber of claim 1, further comprising one or more conduits disposed in the one or more flow openings.

4. The processing chamber of claim 3, wherein the one or more conduits respectively comprise a first opening formed therein.

5. The processing chamber of claim 4, wherein the one or more conduits are respectively positioned to form a second opening between the respective conduit and at least one of the one or more plate walls.

6. The processing chamber of claim 3, wherein the one or more absorptive masses are coupled to the one or more conduits.

7. The processing chamber of claim 3, wherein the one or more plate walls and the one or more conduits respectively include quartz.

8. The processing chamber of claim 1, further comprising one or more heat sources oriented toward the one or more absorptive masses.

9. A chamber kit, comprising:
a plate apparatus comprising one or more flow openings formed in one or more plate walls; and
one or more absorptive masses sized and shaped for disposition in the one or more flow openings, and the one or more absorptive masses having a higher absorptivity than the plate apparatus.

10. The chamber kit of claim 9, wherein the one or more absorptive masses respectively comprise a central opening and one or more outer openings.

11. The chamber kit of claim 10, wherein the central opening extends longitudinally along the respective absorptive mass, and the one or more outer openings are azimuthally spaced from each other.

12. The chamber kit of claim 11, further comprising one or more conduits disposed in the one or more flow openings, wherein the one or more conduits respectively comprise a first opening formed therein, the first opening aligned with the central opening of at least one of the one or more absorptive masses.

13. The chamber kit of claim 12, wherein the one or more conduits are respectively positioned to form a second opening between the respective conduit and at least one of the one or more plate walls.

14. The chamber kit of claim 12, wherein the one or more absorptive masses are coupled to the one or more conduits.

15. The chamber kit of claim 9, further comprising one or more conduits disposed in the one or more flow openings, wherein the one or more flow openings extend into an edge surface of the plate apparatus and inward toward a center of the plate apparatus.

16. The chamber kit of claim 15, wherein the one or more absorptive masses are coupled to the one or more conduits, and the one or more conduits are adjustably disposed in the one or more flow openings to adjust a position of the one or more absorptive masses.

17. A method of substrate processing, comprising:
heating a substrate support in a processing volume of a processing chamber;
flowing one or more process gases between the substrate support and a plate apparatus spaced from the substrate support; and
flowing a gas into one or more flow openings of the plate apparatus and past one or more absorptive masses disposed in the one or more flow openings.

18. The method of claim 17, wherein the gas heats or cools the one or more absorptive masses.

19. The method of claim 17, wherein the gas flows into the one or more flow openings through an inner flow path of the one or more absorptive masses, and the gas flows out of the plate apparatus through an outer flow path between the one or more absorptive masses and one or more plate walls of the plate apparatus.

20. The method of claim 18, wherein the gas flow changes direction after flowing out inner flow path and before flowing into the outer flow path.
